(19) United States
(12) Patent Application Publication
(10) Pub. No.: US 2026/0323868 A1
(43) Pub. Date: Oct. 15, 2026

(54) Data Center Liquid Dielectric Immersion And Plate Cooling System And Method

(71) Applicant: Arnold Castillo Magcale, Danville, CA (US)

(72) Inventor: Arnold Castillo Magcale, Danville, CA (US)

(21) Appl. No.: 19/178,888

(22) Filed: Apr. 15, 2025

(51) Int. Cl. H05K 7/20

(52) U.S. Cl. CPC H05K 7/20236; H05K 7/20254; H05K 7/20263; H05K 7/20272; H05K 7/20281; H05K 7/20772; H05K 7/20836

(57) ABSTRACT

A data center cooling system comprises a heat rejection unit comprising a pump configured to pump a liquid coolant into a manifold mounted on a server rack. The manifold is configured to distribute the liquid coolant to a plurality of servers housed in the server rack. A single tube is connected to the manifold and configured to distribute the liquid coolant in parallel to a plurality of cold plates comprised in the plurality of servers housed in the server rack. The liquid coolant is caused to flow into the plurality of cold plates to absorb heat generated by each of a plurality of CPUs. A return conduit is configured to collect the heated liquid coolant from the plurality of cold plates and transfer it back to the heat rejection unit, having a heat exchanger. An immersion tank is provided.

### FIELD OF THE INVENTION

The present invention relates to an advanced thermal management system for data centers, specifically a hybrid cooling system integrating cold plate and immersion cooling to efficiently dissipate heat from CPUs, GPUs, and network equipment. As modern data centers continue to increase their computing capacity, they generate higher levels of heat, which, if not managed effectively, can lead to performance degradation, higher operational costs, and reduced hardware lifespan.

### BACKGROUND

The rapid advancement of computing technologies has led to an exponential increase in power densities within data centers. High-performance processors such as CPUs and GPUs, networking components like Infiniband, and next-generation Ethernet hardware generate substantial heat that must be effectively dissipated to ensure reliable operation. As processing power increases, traditional cooling techniques struggle to efficiently manage the resulting thermal loads.

Air cooling has been the conventional method for thermal management in data centers, utilizing fans and air conditioning systems to dissipate heat. However, as server density increases, air cooling becomes less effective due to limitations in airflow distribution, rising energy consumption, and the inability to maintain uniform temperature across all components. High-power computing environments exacerbate these inefficiencies, leading to thermal hotspots that can degrade hardware performance and longevity.

Liquid cooling solutions, such as direct-to-chip cold plate cooling, have been developed to address these challenges. Cold plates provide localized cooling by directly contacting the surfaces of heat-generating components and transferring heat to a circulating liquid coolant. This approach enhances thermal efficiency for individual chips but does not effectively manage the residual heat generated by surrounding motherboard components, power modules, and memory units. As a result, additional cooling strategies are required to handle secondary heat loads.

Another emerging technique is immersion cooling, which involves submerging server components in a dielectric liquid that absorbs and dissipates heat. Immersion cooling significantly reduces reliance on air cooling and can effectively manage bulk heat dissipation for entire server racks. However, while immersion cooling provides uniform thermal management, it lacks the precision to target high-heat-generating components, such as CPUs and GPUs, requiring more aggressive cooling to maintain peak performance.

Despite these advancements, data centers face challenges balancing targeted and system-wide cooling. The increasing computational demand in industries such as artificial intelligence, cloud computing, and large-scale data processing necessitates innovative cooling approaches that address localized and residual heat dissipation. Traditional and emerging cooling technologies have inherent limitations, requiring further developments to ensure adequate thermal management across high-density computing environments.

### SUMMARY

The present invention provides a novel hybrid cooling system designed to manage the increasing heat loads in modern data centers efficiently. The system integrates a direct-to-chip cold plate cooling mechanism with an immersion cooling solution, ensuring optimal heat dissipation across various components, including CPUs, GPUs, networking hardware, and power modules. By combining these two technologies, the system maximizes cooling efficiency while addressing the limitations of standalone cooling methods.

Embodiments disclosed comprise a heat rejection unit that circulates a liquid coolant through a manifold mounted on the server rack. This manifold evenly distributes the coolant to multiple servers, each with cold plates designed to absorb heat from high-performance processing units. The liquid coolant effectively transfers the absorbed heat away from the components, allowing it to be collected through a return conduit and redirected to a heat exchanger. The heat exchanger then dissipates the heat into an external cooling medium, restoring the coolant to an optimal temperature before recirculating.

According to a preferred embodiment, an immersion cooling subsystem is implemented, where at least a portion of the servers, including networking gear (which can also include a power supply), is partially submerged in an immersion tank filled with a dielectric liquid. An additional embodiment includes submerging the power supply as well, and alternate embodiments may include completely submerging the servers, including networking gear and power supply. At any rate, this liquid absorbs residual heat from components not directly cooled by the cold plates. The immersion system incorporates circulation mechanisms to enhance heat dissipation, preventing localized temperature spikes and ensuring consistent thermal management across all hardware components.

An embodiment of this hybrid system further comprises a specialized heat bridge, which facilitates efficient heat transfer from motherboards and other secondary heat-generating components to the immersion liquid. This structure helps eliminate potential hotspots, thereby enhancing overall cooling efficiency. Additionally, the system has a network of thermal sensors that continuously monitor temperature variations and optimize cooling performance based on real-time data. The system minimizes energy consumption by adjusting the coolant flow rate and immersion tank circulation in response to workload fluctuations while maintaining superior thermal performance.

Embodiments disclosed include modularity and scalability that allow the cooling infrastructure to adapt to changing data center requirements. The system supports the addition or removal of cold plates, manifolds, or immersion tanks based on evolving server capacity demands. This ensures that data centers can efficiently scale their cooling solutions without overhauling the entire infrastructure, leading to cost savings and increased operational flexibility.

By integrating advanced cooling mechanisms, the hybrid system can provide an optimized thermal management solution that enhances performance, reliability, and energy efficiency. It significantly improves existing cooling techniques by addressing the specific cooling requirements of CPUs, GPUs, and network hardware in high-density data center environments, ensuring sustainable and scalable cooling performance.

### BRIEF DESCRIPTION OF THE DRAWINGS

To further clarify the advantages and features of the present disclosure, a more particular description of the disclosure will be rendered by reference to specific embodiments, which are illustrated in the appended drawings. It is appreciated that these drawings depict only typical embodiments of the disclosure and are therefore not to be considered limiting of its scope. The disclosure will be described and explained in additional specificity and detail in the accompanying drawings.

The subject matter regarded as the invention is particularly pointed out and distinctly claimed in the claims at the conclusion of the specification. The preceding and other aspects, features, and advantages of the invention are apparent from the following detailed description taken in conjunction with the accompanying drawings:

FIG. 1 illustrates a schematic block diagram of a Hybrid Cooling System for the Data Center.

FIG. 2 illustrates a schematic diagram of the Server Rack System.

FIG. 3 illustrates a schematic diagram of the Server and its Components.

FIG. 3A illustrates a Server that comprises a plurality of IT components (CPU, GPU, motherboards and network equipment etc.).

FIG. 3B illustrates a motherboard sealed inside a hinged casing.

FIG. 3C illustrates the motherboard through the opened hinged casing.

FIG. 3D illustrates a Cooling Module that comprises the cold plates.

FIG. 4 illustrates a schematic diagram of a single-loop cooling system for the data center, including one or more server racks, as shown in FIG. 2.

FIG. 5 illustrates a schematic step-based flow chart consisting (FIG. 5A, FIG. 5B, and FIG. 5C)

### DETAILED DESCRIPTION OF THE INVENTION

For the purpose of promoting an understanding of the principles of the invention, reference will now be made to the embodiment illustrated in the drawings, and specific language will be used to describe the same. It will nevertheless be understood that no limitation of the scope of the invention is thereby intended. Such alterations and further modifications in the illustrated system and such further applications of the principles of the invention as illustrated therein would be contemplated as would usually occur to one skilled in the art to which the invention relates. Unless otherwise defined, all technical and scientific terms used herein have the same meaning as commonly understood by one of ordinary skill in the art. The system, methods, and examples provided herein are illustrative only and are not intended to be limiting.

The present disclosure relates to an advanced thermal management system for data centers, specifically a hybrid cooling system integrating cold plate and immersion cooling to efficiently dissipate heat from CPUs, GPUs, and network equipment. As modern data centers continue to increase their computing capacity, they generate higher levels of heat, which, if not managed effectively, can lead to performance degradation, higher operational costs, and reduced hardware lifespan.

The hybrid cooling system of the present disclosure integrates cold plate cooling with immersion cooling to create a comprehensive thermal management solution. Combining direct contact cooling for high-heat-generating components with immersion cooling for broader thermal dissipation optimizes energy efficiency, enhances cooling uniformity, and ensures adaptability to various data center configurations. The invention provides a scalable and modular design, enabling data centers to flexibly accommodate increased computational loads while maintaining stable thermal conditions and reducing energy consumption.

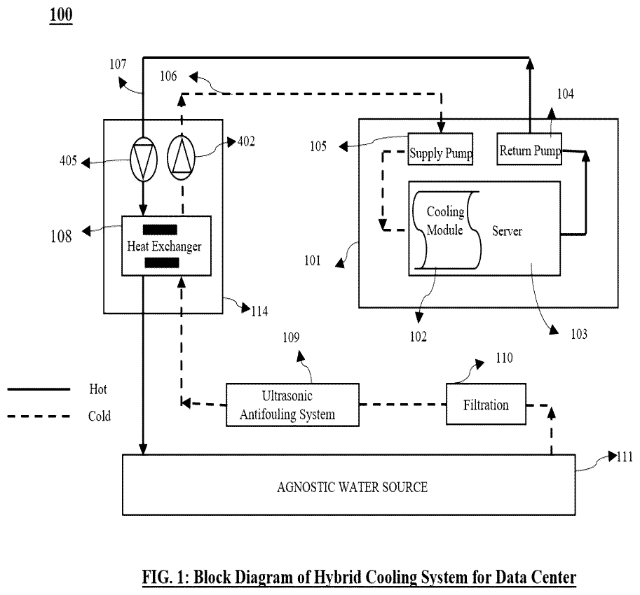

FIG. 1 illustrates a schematic block diagram of a Hybrid Cooling System for the Data Center. The system includes a closed-loop cooling system for the data center. The system comprises a Server Rack 101, which further consists of an inlet pump 105 connected with a cooling module 102 embedded within Server 103, which is connected to an outlet pump 104. A heat exchanger 108 connects directly with inlet pump 105 through inlet fluid line 106, which supplies cold fluid to the cooling module 102. Further, the cold fluid passes through the cold plates of the cooling module 102, and the IT components of server 103 absorb the operational heat and finally eject with the help of outlet pump 104 through outlet fluid line 107 back to the heat exchanger 108. The heat exchanger 108 passes this hot fluid to the agnostic water source 110. Again, the cycle starts with the cold fluid from the agnostic water source 110 flowing through the filter 110 and ultrasonic antifouling system 109 to the heat exchanger 108 and through inlet fluid, line 106 getting through server 101 with the help of inlet pump 105. The primary function of the Cooling module 102 and Heat exchanger 108 is to circulate working fluid through the closed loop and transfer heat from the internal server to the external cooling unit.

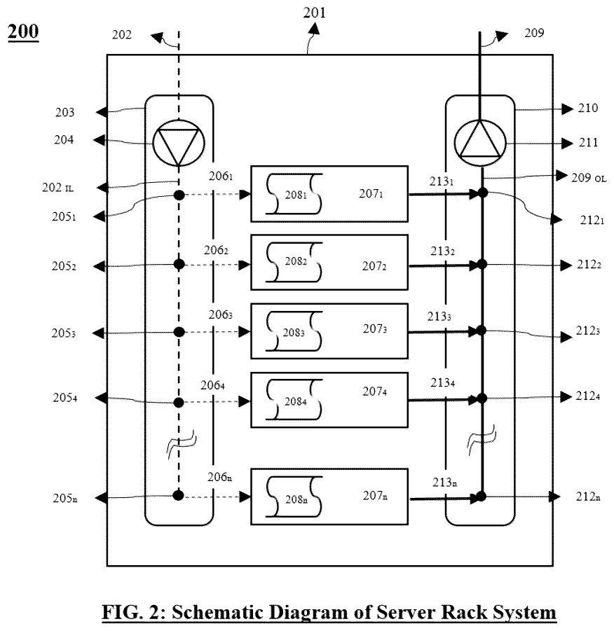

FIG. 2 illustrates a Schematic Diagram of the Server Rack System. The Server Rack 200 includes rack 201, within which an inlet manifold 203, an outlet manifold 210, and a plurality of servers 207, numbered 207₁-208ₙ in the drawing. Each server 207 includes one or more information technology (IT) components disposed therein. An IT component may consist of one or more processors, motherboards, memory, and/or a storage device, etc., that may generate heat during operations. Each of servers 207 includes at least one liquid-cooled cooling module 208—server 207₁ includes cooling module 208₁, server 207₂ includes cooling module 208₂, and so on till server 207ₙ includes cooling module 208ₙ—that is thermally coupled to electronic components on the servers so that they can remove heat from the components to which they are thermally coupled. In one embodiment, cooling modules 208 can be cold plates; in other embodiments, they can be another type of liquid-cooled cooling module.

In the illustrated embodiment, inlet manifold 203 and outlet manifold 210 are vertically positioned on opposite sides of rack 201, but in other embodiments, the inlet and outlet manifolds can be arranged differently. For instance, in one embodiment, one manifold can be placed horizontally across the top of the rack and the other horizontally across the bottom of the rack. In other embodiments, both manifolds can be positioned horizontally along the top of the rack, or both can be positioned horizontally along the bottom of the rack. In yet other embodiments, both inlet manifold 203 and outlet manifold 210 can be combined in a single housing that can be positioned in any orientation anywhere in the rack.

The illustrated embodiment has a plurality of servers 207, numbered 207₁-207ₙ, but in other embodiments, rack 201 can include fewer servers 208 than shown. Each cooling module 208 on server 207 is coupled to inlet manifold 203 by a sub-loop supply line 206 and is connected to the outlet manifold 210 via a sub-loop return line 213. Thus, for instance, server 207₁ is coupled to inlet manifold 203 by sub-loop supply line 206₁ and to the outlet manifold 210 by sub-loop return line 213₁, and similarly for the other servers shown. One or more cooling modules 208 on each server 207 are thermally coupled to liquid-cooled electronic components on the server. In various embodiments, for instance, the electronic components can be motherboards, microprocessors, graphics processors, or other types of elements that generate enough heat that it is beneficial or desirable to use liquid cooling to cool them.

According to an embodiment, inlet manifold 203 includes an embedded supply pump 204, a fluid line 202_{IL}, and one or more sub-loop supply lines 206. The illustrated embodiment has a plurality of sub-loop supply lines 2061-206n, but other embodiments of server rack 200 can include fewer sub-loop supply lines than shown. Supply pump 204 has its inlet coupled to main supply line 202 and its outlet to fluid line 202_{IL}. Sub-loop supply lines 206 are connected to fluid line 202_{IL} by fluid connectors 205. Embedded pump 204 receives cool working fluid from main supply line 202 and pumps it into fluid line 202_{IL}, which then distributes the received fluid into sub-loop supply lines 206. In one embodiment, pump 204 is a variable-speed pump so that it can be used to control the supply of fluid to cooling modules 208, for instance, depending on their temperature (e.g., if a temperature rise is sensed in the rack, pump 204 can speed up to deliver more working fluid to the cooling modules) or a server load. However, in other embodiments, pump 204 does not need to be a variable-speed pump. In some embodiments, pump 204 can be a high-reliability pump-that is, a pump with a low mean time between failures (MTBF). Pump 204 is referred to as an embedded pump because it is positioned within the manifold 203 and, as such, forms a part of the manifold.

Embodiments disclosed comprise fluid line 202_{IL} and sub-loop supply lines 206, which are coupled to the outlet of embedded pump 204 to deliver cool working fluid to cooling modules 208. In one embodiment, fluid line 202_{IL} can be a single pipe or multiple sections of pipe coupled to the outlet of embedded pump 204. Still, in other embodiments, fluid line 202_{IL} can be a single hose or multiple hose sections coupled to the outlet of embedded pump 204. Fluid line 202_{IL} is coupled to sub-loop supply lines 206 by fluid connectors 205. In one embodiment, fluid connectors 205 can be Y-fittings, T-fittings, or other type of fluid connector as would be apparent to a person having ordinary skill in the art. In other embodiments, fluid connectors 205 can be valves that allow certain sub-loops to be turned off-for instance, if a server 207 and its corresponding cooling module 208 are removed from the rack. In various embodiments, fluid connectors 205 need not all be of the same type.

The inlet manifold 203 contains all the components, including an embedded pump 204, fluid line 202_{IL}, fluid connectors 205, and portions of sub-loop supply lines 206₁-206ₙ. In one embodiment, inlet manifold 203 can be leak-proof or leak-resistant so that if any component within it leaks, it can slow down or prevent the leak from spreading into the rest of the server rack, which could damage servers 207.

Outlet manifold 210 is structured similarly to inlet manifold 203. The outlet manifold includes an embedded return pump 211 and a fluid line 209_{OL}. Fluid line 209_{OL} is, in turn, coupled to sub-loop return lines 213 by fluid connectors 212. All the described elements can have the same characteristics as the analogous elements described in input manifold 203. Each cooling module 208 is then coupled to the inlet manifold 203 by sub-loop supply lines 206 and to the outlet manifold 210 by outlet by sub-loop return lines 206.

In the operation of rack 201, supply pump 204 pumps cool working fluid received from main supply line 202 into fluid line 202_{IL}, which then distributes the cool working fluid into sub-loop supply lines 206 via fluid connectors 205. The cool working fluid then flows into cooling module 208, which absorbs heat from the components to which the cooling modules are attached. The heat absorbed by the working fluid increases its temperature, so after flowing through cooling module 208, it is considered hot working fluid instead of cool. The hot working fluid flows out of cooling modules 208 through sub-loop return lines 213 and connectors 212 into fluid line 209_{OL}. Return pump 211, then pumps the hot working fluid from fluid line 209_{OL} into main return line 209.

The illustrated two-pump configuration with a supply pump and a return pump is considered a redundancy design. The pump speeds of supply pump 204 and return pump 211 can be adjusted based on different control signals, which enables more accurate control of the fluid flow through the rack based on the rack-level cooling requirements (rack heat load). And because the pumps are embedded in the manifolds, their response can be more rapid. Another function of the manifold pump control is that when an individual rack requires a different fluid flow rate due to different cooling requirements from the rack heat load, the manifold pump can be adjusted accordingly and precisely. This enables the achievement of localized control.

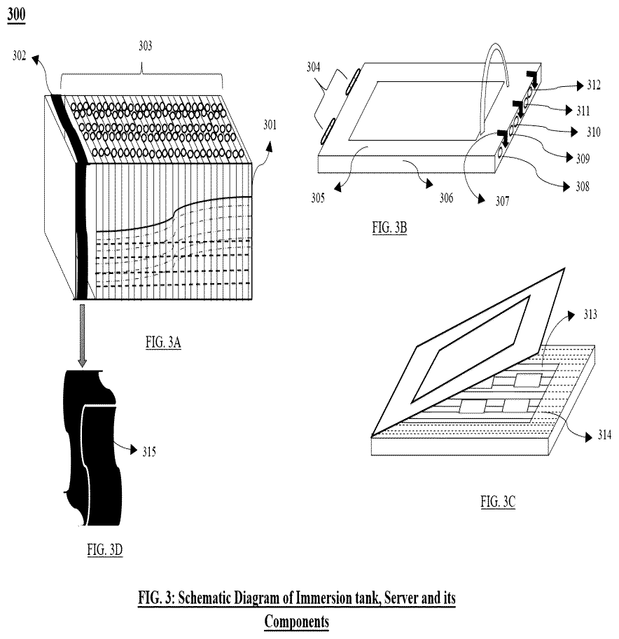

FIG. 3A illustrates a Server that comprises a plurality of IT components, which may include one or more processors, motherboards, memory, and/or a storage device, etc., that may generate heat during operations; in this case, let's say motherboards are stacked in an immersive pod comprising dielectric liquid in a cabinet according to an embodiment. FIG. 3A depicts cabinet 301, comprising Cooling module 302 and a plurality of motherboards 303 inside the hinged casing arrayed vertically, connected to the fluid lines.

FIG. 3B illustrates a motherboard sealed inside a hinged casing 305 according to an embodiment. The motherboard is cased within the sealed, openable casing comprising hinge 304, water-tight seal envelopes 306, and locking mechanism 307. The sealed casing further comprises a power connection point 308 for the motherboard, a liquid inlet 309, and a corresponding liquid outlet 310. Additionally and preferably, the sealed casing includes fiber optic connecting 311 for the motherboard and copper RJ45 connecting 312.

FIG. 3C illustrates the motherboard through the opened hinged casing. Depicted in FIG. 3C is motherboard 313 and filled with liquid 314.

FIG. 3D illustrates a cooling module that comprises the cold plates 315. In at least one embodiment, the cold plate can work independently. It can cool at least one computing device associated with a fluid or local coolant-enabled cold plate 315 via provided fluid lines for a local cooling loop and fluid associated with a liquid source.

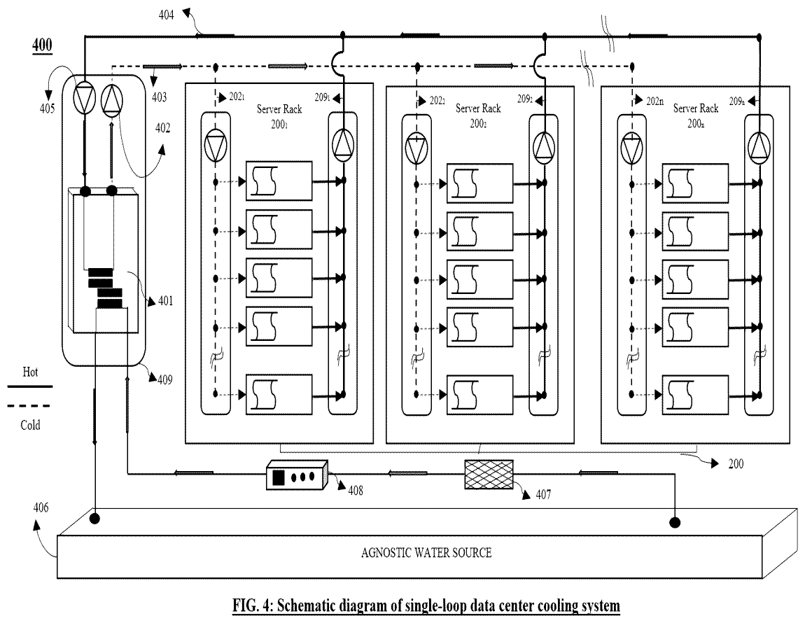

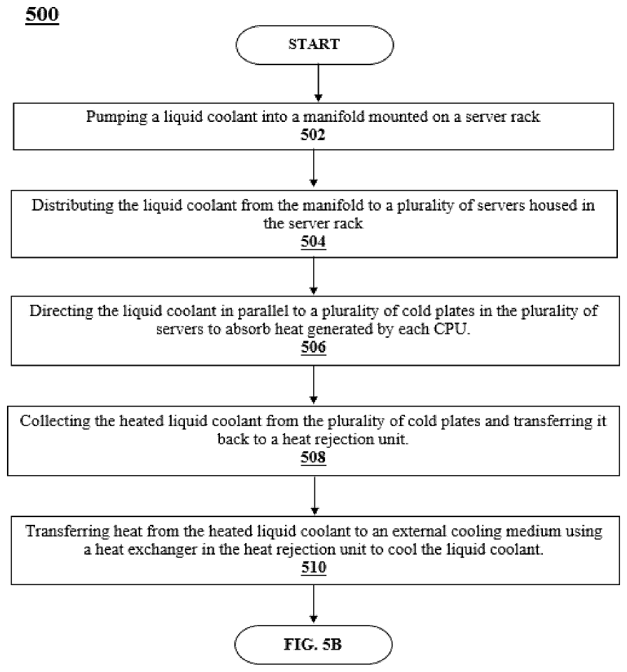

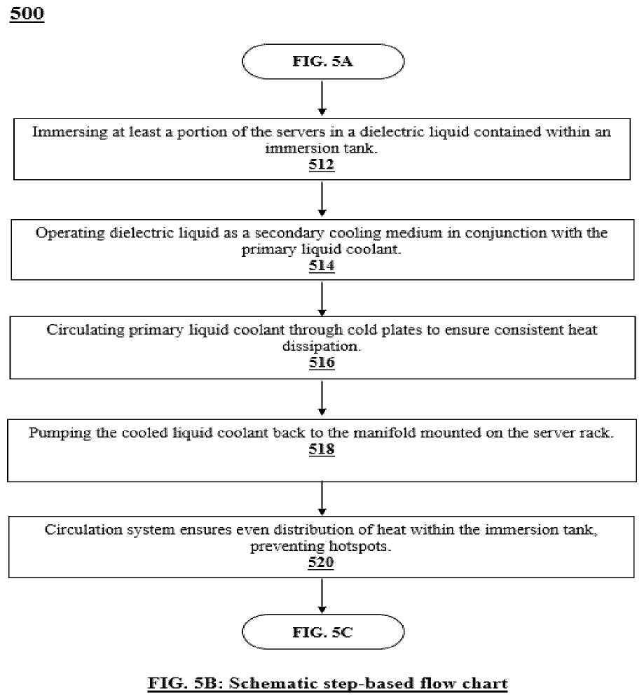

FIG. 4 illustrates an embodiment of a data center cooling system. The cooling system comprises multiple server racks, each of which houses a combination of CPUs, GPUs, power supplies, and networking equipment. A central heat exchanger is incorporated to facilitate heat transfer from the working fluid to an external agnostic water source. The system comprises an inlet pump that draws cool working fluid from the heat exchanger and directs it into the supply lines of the server racks. The cooled liquid is then distributed through individual manifolds, where it flows into cold plates that are in direct contact with heat-generating components.

As the coolant absorbs heat from the processors and other electronic components, its temperature rises, and the heated fluid is directed through outlet manifolds back to the return line. The heated coolant then reaches the heat exchanger, where it undergoes thermal exchange with the external cooling medium. The heat exchanger efficiently removes excess heat before returning the cooled fluid back into the cycle, ensuring continuous and stable thermal regulation.

In addition to direct-to-chip cooling via cold plates, the system incorporates an immersion cooling mechanism. Certain server racks contain components that are partially or fully submerged in a dielectric liquid bath. This liquid serves as an additional thermal medium, passively absorbing heat from networking hardware, memory units, and auxiliary power systems. To maintain thermal equilibrium within the immersion tank, a circulation system continuously moves the dielectric liquid, preventing localized overheating.

FIG. 4 illustrates an embodiment of a primary cooling loop data center cooling system 400. The cooling system 400 comprises a plurality of server racks 200 (see FIG. 2), such as server racks 200₁-200ₙ, a heat exchanger 401 along with system inlet 402 and outlet pump 405, an agnostic water source 405, a filter 406, and an ultrasonic antifouling system 407 which remains outside the data center. In the illustrated embodiment, heat exchanger 401 is a liquid-to-liquid heat exchanger that transfers heat from the working liquid that circulates through server racks 200 into the agnostic water source 405. In embodiments in which heat exchanger 401 is a liquid-to-liquid heat exchanger, the heat exchanger can use a natural water resource such as seawater or lake water. However, in other embodiments, heat exchanger 401 can be a different type of heat exchanger, such as a liquid-to-air heat exchanger. In embodiments in which heat exchanger 401 is a liquid-to-air heat exchanger 401, it can be a dry cooler, a cooling tower, or an evaporative cooler.

System inlet pump 402 has its inlet coupled to the liquid outlet of heat exchanger 401 and has its outlet coupled to system supply line 403. The main supply line 202 of each server rack 200 is then coupled to system supply line 403. System return line 404 is coupled to the main return line 209 of each server rack 200 and to the liquid inlet of the heat exchanger 401. Different data center infrastructures may require a slight modification on the facility liquid piping, but in any event, cooling system 400 is a primary cooling loop system.

In various embodiments, system inlet and outlet pump 402 and 405, respectively, can be either packaged within the heat exchanger 401 or designed as an external component. Other embodiments can have multiple system pumps for redundancy, high flow rate, or high-pressure requirements. The system pump and manifold pump can control the fluid flow rate together. Basically, the system pump provides a major driving force for the fluid flowing in the system, and the manifold pumps have two main functions: providing additional driving force and controlling the flow rate based on the rack heat load. Different control strategies for the system pump and manifold pump can be developed.

In operation, system inlet pump 402 pumps cool working fluid from the heat exchanger 401 into system supply line 403, which then supplies the cool working fluid to the main supply line 202 of each server rack 200. The embedded supply pump within the inlet manifold of each server rack 200 pumps the cool working fluid into the sub-loop supply lines, which then deliver the cool working fluid to the cooling modules on the servers. As the working fluid circulates through cooling modules on the servers, it absorbs heat and becomes hotter so that hot working fluid emerges through sub-loop return lines and into the outlet manifold. The embedded return pump within the outlet manifold pumps the hot working fluid into system return line 404, which returns the hot working fluid to heat exchanger 401. As the hot working fluid circulates through heat exchanger 401 cold water, for instance from the agnostic water source 405, circulates through filter 406 and ultrasonic antifouling system 407, to heat exchanger 401 and removes heat from the hot working fluid, so that it can again be circulated to the server racks 200 through system pump 402.

In at least one embodiment, a cooling distribution unit instance heat exchanger 401 is used between a primary cooling loop and a second or secondary cooling loop to enable absorption of heat from a second or secondary cooling loop to a primary cooling loop. In at least one embodiment, a secondary cooling loop can access various plumbing into a server tray as required, in an aspect. In at least one embodiment, loops are illustrated as line drawings, but a person of ordinary skill would recognize that one or more plumbing features may be used. In at least one embodiment, flexible polyvinyl chloride (PVC) pipes may be used along with associated plumbing to move fluid along in each provided loop. In at least one embodiment, one or more coolant pumps may be used to maintain pressure differences within coolant loops to enable movement of coolant according to temperature sensors in various locations, including in one or more racks 201, and/or in server boxes or server racks within one or more racks 200.

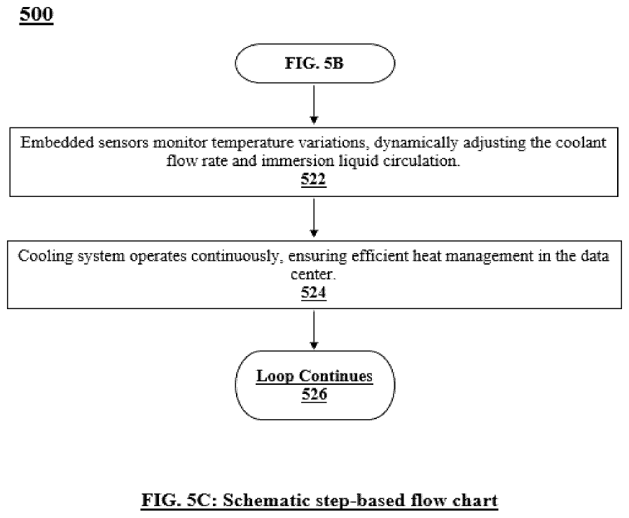

FIG. 5 illustrates schematic flowchart drawings outlining the step-by-step operation of the hybrid cooling system, detailing the sequence of coolant circulation, heat absorption, heat dissipation, and dynamic feedback control. Each figure (FIG. 5A, FIG. 5B, and FIG. 5C) represents a critical phase of the operation of a hybrid cooling system for data centers that integrates cold plate cooling and immersion cooling technologies to ensure efficient heat dissipation from high-performance computing components.

According to a preferred embodiment, FIG. 5A illustrates a schematic Step-Based Flowchart for Initialization & Coolant Circulation. Step 502 illustrates the initialization phase of the hybrid cooling system. The cooling process begins by pumping a liquid coolant into a manifold that is mounted on a server rack. The manifold acts as a central distribution system, supplying coolant to multiple servers within the rack. This step ensures that the cooling system is primed and ready to absorb heat from high-powered components such as CPUs and GPUs. Once the coolant reaches the manifold, in step 504, it is distributed to multiple servers housed within the server rack. The manifold ensures an even and controlled distribution of coolant, preventing variations in flow rate and ensuring that each server receives an adequate supply of cooling fluid.

As depicted in FIG. 5A, in step 506 the coolant is then directed in parallel to multiple cold plates installed within the servers. Each cold plate is in direct contact with heat-generating components such as CPUs and GPUs, facilitating efficient heat absorption. The parallel cooling approach ensures uniform temperature regulation across all processors, preventing thermal bottlenecks. Step 508 illustrates that as the coolant absorbs heat from the CPUs and GPUs, its temperature increases. The heated coolant is collected from the cold plates and transferred to the heat rejection unit via a return conduit. This step is crucial in ensuring that the heat absorbed from the processors is effectively removed from the system.

As illustrated in FIG. 5B, according to an embodiment in step 510, within the heat rejection unit, the heat exchanger facilitates heat transfer from the heated coolant to an external cooling medium, such as a chilled water loop or an air-cooled condenser. This process significantly reduces the temperature of the coolant before it is reintroduced into the system. The heat exchanger plays a pivotal role in maintaining an energy-efficient and sustainable cooling loop. Step 512 explains that apart from cold plate cooling, the system also integrates immersion cooling. In this step, at least a portion of the servers are immersed in a dielectric liquid contained within an immersion tank. The dielectric fluid passively absorbs residual heat from networking hardware, power modules, and auxiliary components that are not directly cooled via cold plates.

According to an embodiment, in step 514, the dielectric liquid operates as a secondary cooling medium, working in conjunction with the primary liquid coolant. This dual cooling approach ensures a comprehensive heat dissipation process by managing both direct-to-chip and broad-spectrum thermal loads within the data center infrastructure. As shown in FIG. 5B in step 516 the primary coolant is continuously circulated through cold plates to maintain consistent heat dissipation. This ensures that processors operate within optimal temperature limits, preventing thermal throttling and hardware degradation.

FIG. 5C illustrates in step 518 that after undergoing thermal exchange within the heat rejection unit, the cooled coolant is pumped back to the manifold on the server rack. This closes the cooling loop and ensures a continuous cycle of heat absorption and rejection, maintaining stable operating temperatures within the data center. In step 520, within the immersion tank, the circulation system ensures even heat distribution throughout the dielectric liquid. This prevents localized hotspots and maintains a uniform thermal environment for all submerged components. Proper circulation enhances the overall efficiency of the immersion cooling subsystem.

According to an embodiment, in step 522 the embedded temperature sensors continuously monitor thermal variations throughout the system. These sensors dynamically adjust the coolant flow rate and immersion liquid circulation based on real-time heat loads. This adaptive approach ensures energy-efficient cooling by optimizing cooling intensity based on workload fluctuations. In step 524 the hybrid cooling system operates continuously, maintaining an efficient thermal balance within the data center. The combination of cold plate cooling, immersion cooling, and real-time sensor feedback ensures stable thermal conditions even under high computational loads. The final step 526, as depicted in FIG. 5C, confirms that the cooling cycle repeats continuously, allowing the system to adapt dynamically to changing computational demands. This automated and self-regulating loop ensures long-term cooling stability and reliability in high-density computing environments.

According to a preferred embodiment, the System Architecture of the hybrid cooling system is designed as a multi-faceted thermal management solution, integrating direct-to-chip cold plate cooling with immersion cooling to handle the varying heat loads generated by CPUs, GPUs, and other high-performance components. The system consists of a liquid-based cold plate subsystem that provides targeted cooling to heat-intensive processors and an immersion cooling subsystem that submerges networking and auxiliary components in a dielectric liquid for broad heat dissipation. A heat rejection unit facilitates heat removal from the circulating liquid coolant, ensuring continuous operation at optimal temperatures. The system also includes a thermal bridge structure to transfer excess heat from the motherboard to the immersion cooling fluid, ensuring uniform temperature regulation across all server components. A hybrid cooling strategy maximizes cooling efficiency while minimizing energy consumption and operational costs. The modular design further allows data centers to scale their cooling infrastructure in response to fluctuating computational demands.

Embodiments disclosed comprise the cold plate subsystem, a crucial component of the hybrid cooling system, designed to provide direct-to-chip cooling for high-power processors such as CPUs and GPUs. Each server is equipped with cold plates that are securely affixed to the surface of these heat-generating components to ensure efficient thermal transfer. The cold plates are constructed from highly conductive materials like copper or aluminum to facilitate rapid heat dissipation.

According to one embodiment, a network of microchannels is integrated within each cold plate to maximize surface area contact with the liquid coolant. These microchannels enhance convective heat transfer by increasing the interaction between the coolant and the heated surfaces, resulting in a more efficient temperature reduction. The liquid coolant, carefully selected for its high thermal capacity and non-corrosive properties, is circulated through the microchannels at a controlled flow rate to maintain optimal cooling performance.

An embodiment includes the cooling fluid distributed to the cold plates through a centralized manifold system that ensures uniform flow across multiple processors. The manifold is engineered to balance pressure distribution, preventing variations in flow that could lead to localized overheating or inefficient cooling. To further enhance reliability, the cold plate subsystem incorporates thermal sensors that continuously monitor temperature levels and adjust coolant flow rates accordingly, ensuring real-time adaptive cooling based on the system's dynamic thermal loads.

Additionally, the cold plate subsystem is designed for modularity, allowing for easy integration, maintenance, or replacement of individual cold plates without requiring significant downtime. This feature ensures that data centers can efficiently scale their cooling solutions as computing demands evolve. Integrating the cold plate subsystem with the immersion cooling subsystem allows for a comprehensive and highly efficient hybrid cooling strategy, effectively dissipating heat at both localized and system-wide levels.

An embodiment further comprises the immersion cooling subsystem, designed to complement the cold plate subsystem by dissipating residual heat from components not directly cooled by cold plates. At least a portion of the servers, including networking equipment, power modules, and auxiliary electronics, are partially or fully submerged in an immersion tank filled with a non-conductive dielectric liquid. This liquid is a highly efficient thermal medium that absorbs heat from the submerged components, preventing thermal hotspots and ensuring uniform temperature regulation throughout the system.

According to an embodiment, the immersion tank incorporates an active circulation system that maintains continuous fluid movement to enhance thermal performance. The circulation system prevents localized overheating by ensuring the dielectric liquid remains in constant motion, distributing heat away from the servers and toward a designated heat exchanger. This mechanism facilitates rapid heat dissipation, improving overall system efficiency.

According to an embodiment, the immersion cooling subsystem also integrates a heat bridge mechanism that transfers excess heat from the motherboard and secondary heat-generating components to the immersion fluid. This feature ensures that even components not in direct contact with the liquid experience effective thermal management, preventing performance degradation due to overheating.

Additionally and alternatively, for enhanced monitoring and control, the immersion cooling subsystem is equipped with thermal sensors that provide real-time data on temperature variations within the tank. These sensors enable dynamic adjustments to the circulation rate and cooling intensity, optimizing energy efficiency based on workload fluctuations. The system is further designed with modular scalability, allowing data centers to expand or modify their immersion cooling infrastructure as computational demands evolve.

Therefore, the hybrid cooling system achieves a balanced and highly efficient thermal management strategy by integrating immersion with the cold plate subsystem. The combination of targeted chip-level cooling and broad-spectrum immersion cooling ensures that all critical server components maintain optimal operating temperatures, enhancing system reliability and extending hardware longevity.

According to an embodiment, the heat rejection mechanism is a critical component of the hybrid cooling system, responsible for efficiently dissipating heat absorbed by both the cold plate and immersion cooling subsystems. It comprises a heat exchanger that facilitates thermal energy transfer from the heated liquid coolant to an external cooling medium, such as a chilled water loop or an evaporative cooling tower. This ensures the coolant is restored to an optimal temperature before recirculating through the system.

Embodiments disclosed comprise the heat rejection unit, designed to accommodate variable cooling loads by incorporating a dynamic pump system that operates at adjustable speeds. This allows the system to optimize energy consumption by increasing or decreasing the coolant flow rate based on real-time thermal demands. Additionally, the heat exchanger is constructed from highly efficient, corrosion-resistant materials to maximize heat dissipation and ensure long-term durability.

According to an embodiment, to further enhance performance, the heat rejection mechanism integrates redundant pumps and heat exchangers, providing failover capabilities to maintain continuous operation during component failure. This redundancy ensures minimal downtime and enhances the reliability of the cooling system. Integrating thermal sensors enables real-time monitoring of coolant temperatures, allowing automated adjustments to flow rates and heat exchanger performance to prevent overheating and improve overall efficiency.

By incorporating an intelligent and adaptive heat rejection mechanism, the hybrid cooling system effectively manages the dissipation of waste heat while minimizing energy consumption and operational costs. The synergy between the cold plate, immersion cooling, and heat rejection subsystems ensures a balanced and highly efficient thermal management solution for high-density data center environments. Additionally, the embodiments disclosed can be configured to act as redundant cooling systems for data centers. For example if the cold plate cooling system were to malfunction, the immersion tank system would increase the flow of the fluid to make up the heat rejection lost by the cold plate and vice versa. This would be triggered by the thermal sensors.

Additionally and alternatively, the integration of cold plate and immersion cooling in this hybrid system is designed to maximize thermal efficiency while ensuring reliable and consistent cooling across all high-performance computing components. The cold plates provide direct, localized cooling for high-heat-generating components such as CPUs and GPUs, utilizing liquid coolant to extract heat efficiently. This targeted cooling prevents excessive temperature build-up at the processor level, where heat flux is the highest.

In contrast, the immersion cooling subsystem offers broad-spectrum cooling by submerging networking hardware, power modules, and motherboard components in a dielectric liquid. This method enables uniform thermal dissipation and eliminates hotspots that may develop in areas not directly in contact with the cold plates. The immersion fluid actively absorbs residual heat from components not covered by the cold plate cooling system, ensuring a comprehensive thermal management solution.

According to an embodiment, a key feature of the integration includes a heat bridge mechanism, which facilitates the transfer of excess heat from the motherboard and secondary components into the immersion cooling fluid. This thermal transfer system effectively enhances cooling performance by extending the benefits of immersion cooling to all heat-generating elements within the server infrastructure. The heat bridge comprises high-conductivity materials that enable efficient thermal exchange, preventing localized temperature spikes and optimizing overall system stability.

Furthermore, integrating both cooling approaches allows for adaptive thermal balancing, wherein the system dynamically allocates cooling resources based on real-time heat load measurements. Smart thermal sensors in the system monitor temperature variations and adjust coolant flow rates and immersion liquid circulation accordingly. This ensures that both cooling methods work harmoniously to maximize heat dissipation while minimizing energy consumption.

The disclosed embodiments explain that the hybrid system also incorporates modular scalability, enabling data centers to expand or reconfigure their cooling infrastructure as computational demands evolve. The integration of cold plates and immersion cooling within a single system provides an advanced, energy-efficient cooling strategy tailored for high-density computing environments, ensuring long-term sustainability and operational efficiency.

A preferred embodiment of the method includes a structured and efficient process to manage the heat loads generated by high-performance computing components. The method begins by pumping liquid coolant into a manifold mounted on a server rack. This manifold functions as a central distribution point, ensuring that coolant is evenly supplied to the cold plates installed within each server. These cold plates are designed to extract heat directly from CPUs and GPUs, preventing excessive temperature build-up and maintaining optimal processing conditions.

The architecture of the embodiments disclosed takes a unique approach as the coolant absorbs heat from the cold plates, becomes thermally saturated, and exits the servers through a return conduit. This heated coolant is then directed toward a heat exchanger, where it releases the absorbed heat to an external cooling medium, such as a chilled water loop. This cooling cycle ensures the coolant is continuously refreshed and effectively manages processor temperatures.

According to an additional embodiment, while the cold plates focus on dissipating heat from CPUs and GPUs, the immersion cooling subsystem manages residual heat from networking hardware, power modules, and other auxiliary components. These components are partially or fully submerged in a dielectric liquid within an immersion tank, allowing passive heat absorption. The immersion liquid is actively circulated to enhance cooling performance, preventing localized overheating and maintaining a stable temperature environment.

Embodiments disclosed comprise an advanced dynamic thermal feedback mechanism, which continuously monitors temperature fluctuations through embedded sensors. The system adjusts coolant flow rates and immersion tank circulation based on real-time data to ensure precise and efficient thermal regulation. This adaptive approach optimizes energy consumption while maintaining a consistent and reliable cooling performance. Further, by combining direct cold plate cooling with immersion-based thermal dissipation, the hybrid system achieves superior efficiency, ensuring the sustained performance of high-density computing environments while significantly reducing operational costs.

The present embodiments offer a range of advantages over conventional data center cooling solutions by effectively integrating cold plate and immersion cooling technologies. This approach significantly enhances cooling efficiency by combining direct-to-chip cooling for high-performance processors with immersion cooling for networking hardware and auxiliary components. The system ensures comprehensive thermal management by utilizing both methods in tandem, reducing localized hotspots and maintaining uniform temperature distribution across all critical components. A key advantage of this system is its scalability and modular design, which allows data centers to efficiently expand or reconfigure their cooling infrastructure as computational demands evolve. The ability to add or remove cold plates, immersion tanks, and cooling manifolds without major infrastructure modifications provides data centers with greater flexibility, ensuring long-term adaptability and cost savings.

According to a preferred embodiment, energy efficiency is another crucial benefit of this hybrid system. The inclusion of variable-speed pumps and dynamic thermal sensors enables real-time monitoring and adjustment of coolant flow rates and immersion liquid circulation. This ensures that cooling resources are allocated precisely where needed, minimizing unnecessary energy consumption while maintaining optimal performance. The result is a significant reduction in overall operational costs and an improved power usage effectiveness (PUE) ratio.

The disclosed embodiments also offer enhanced reliability and redundancy. Using redundant pumps and heat exchangers ensures uninterrupted operation even during component failure, reducing the risk of overheating and system downtime. Furthermore, the isolated cooling paths for cold plates allow individual maintenance without disrupting the entire system, thereby improving serviceability and operational continuity.

Finally, integrating advanced cooling strategies promotes sustainability by reducing reliance on traditional air conditioning systems, lowering water consumption, and minimizing carbon footprint. This makes it a highly effective and environmentally friendly solution for next-generation high-density computing environments.

Since various possible embodiments might be made of the above invention, and since multiple changes might be made in the embodiments above set forth, it is to be understood that all matter herein described or shown in the accompanying drawings is to be interpreted as illustrative and not to be considered in a limiting sense. Thus, it will be understood by those skilled in the art of hybrid cooling systems for data centers by integrating cold plate cooling and immersion cooling to efficiently dissipate heat from CPUs, GPUs, and network equipment and more particularly, for the Hybrid Cooling Systems for Data Centers Utilizing Cold Plate And Immersion Cooling, that although the preferred and alternate embodiments have been shown and described in accordance with the Patent Statutes, the invention is not limited thereto or thereby.

The figures illustrate the architecture, functionality, and operation of possible implementations of systems, methods, and computer program products according to various embodiments of the present invention. It should also be noted that, in some alternative implementations, the functions noted/illustrated may occur out of the order noted in the figures.

The terminology used herein is for the purpose of describing embodiments only and is not intended to be limiting to the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components but do not preclude the presence or addition of one or more other features, integers, steps, operations, elements, components, and/or groups thereof.

The present invention and some of its advantages have been described in detail for some embodiments. It should be understood that although the system and process are described with reference to the Hybrid Cooling System for Data Centers Utilizing Cold Plate and Immersion Cooling, the system and method are highly reconfigurable and may be used in other systems as well. It should also be understood that various changes, substitutions, and alterations can be made herein without departing from the spirit and scope of the invention as defined by the appended claims. An embodiment of the invention may achieve multiple objectives, but not every embodiment falling within the scope of the attached claims will achieve every objective. Moreover, the scope of the present application is not intended to be limited to the embodiments of the process, machine, manufacture, and composition of matter, means, methods, and steps described in the specification. A person having ordinary skill in the art will readily appreciate from the disclosure of the present invention that processes, machines, manufacture, compositions of matter, means, methods, or steps presently existing or later to be developed are equivalent to and fall within the scope of, what is claimed. Accordingly, the appended claims are intended to include processes, machines, manufacture, and compositions of matter, means, methods, or steps within their scope.

We claim:

1. A data center cooling system comprising:
a heat rejection unit comprising a system-level inlet pump, a system-level outlet pump, and a heat exchanger;
wherein the system-level inlet pump is configured to pump a liquid coolant into a system supply line;
an inlet manifold mounted on a server rack and coupled to the system supply line, wherein the inlet manifold is configured to distribute the liquid coolant to a plurality of servers housed in the server rack;
a single tube connected to a supply pump comprised in the inlet manifold and configured to distribute the liquid coolant in parallel to a plurality of cold plates comprised in the plurality of servers housed in the server rack;
wherein the liquid coolant is caused to flow into the plurality of cold plates to absorb heat generated by corresponding plurality of central processing units (CPUs);
an outlet manifold mounted on the server rack and coupled to the plurality of cold plates, the outlet manifold configured to collect heated liquid coolant from the plurality of cold plates;
system return line coupled between a return pump comprised in the outlet manifold and the system-level outlet pump, configured to receive the heated liquid coolant from the plurality of cold plates and transfer it back to the heat rejection unit via the system-level outlet pump; and
wherein the heat exchanger comprised in the heat rejection unit, is configured to transfer heat from the heated liquid coolant to an external cooling medium to cool the liquid coolant back to its original temperature.

2. The data center cooling system of claim 1, wherein manifolds are made of a material with high thermal conductivity to enhance uniform coolant distribution efficiency to the servers housed in the server rack.

3. The data center cooling system of claim 1, further comprising a thermal sensor, wherein the data center cooling system is configured to optimize cooling by adjusting flow rate of the liquid coolant pumped by the system-level inlet pump through the system supply line and the inlet manifold based on real-time thermal sensor feedback from each CPU.

4. The data center cooling system of claim 1, wherein the liquid coolant comprises a non-corrosive, environmentally friendly liquid with a high thermal capacity and low freezing point.

5. The data center cooling system of claim 1, wherein the system-level inlet pump and the system-level outlet pump of the heat rejection unit are configured to operate at variable speeds or frequencies to optimize energy consumption during varying cooling demand periods.

6. The data center cooling system of claim 1, further comprising a backup system-level pump and a secondary manifold to ensure uninterrupted operation during maintenance or system failures.

7. The data center cooling system of claim 1, wherein each cold plate comprises a plurality of microchannels to increase surface area for enhanced heat transfer from the CPUs to the liquid coolant.

8. The data center cooling system of claim 1, further comprising modular components to enable addition or removal of one or more manifolds, cold plates, or immersion tanks to accommodate increased or decreased server capacity.

9. The data center cooling system of claim 1, wherein the heat rejection unit further comprises an external liquid-to-liquid heat exchanger for transferring heat to an external chilled water loop.

10. The data center cooling system of claim 1, wherein manifolds are configured to isolate and bypass individual cold plates during maintenance without disrupting operation of the system.

11. (canceled)

12. (canceled)

13. A method for cooling a data center, comprising:
pumping a liquid coolant into a system supply line using a system-level inlet pump of a heat rejection unit;
delivering the liquid coolant from the system supply line into an inlet manifold mounted on a server rack, the inlet manifold distributing the liquid coolant to a plurality of servers housed in the server rack;
directing the liquid coolant in parallel to a plurality of cold plates in the plurality of servers to absorb heat generated by a corresponding plurality of central processing units (CPUs);
directing heated liquid coolant from the plurality of cold plates into an outlet manifold mounted on the server rack;
transferring the heated liquid coolant from the outlet manifold through a system return line back to the heat rejection unit; and
transferring the heat from the heated liquid coolant to an external cooling medium via a heat exchanger in the heat rejection unit.

14. The method of claim 13, further comprising monitoring thermal sensor feedback to adjust flow rate of the liquid coolant pumped by the system-level inlet pump through the system supply line and the inlet manifold in real time based on a cooling demand of each of the plurality of CPUs.

15. The method of claim 13, further comprising operating the system-level inlet pump and system-level outlet pump of the heat rejection unit at variable speeds or frequencies to minimize energy consumption during low cooling demand periods.

16. The method of claim 13, further comprising isolating specific cold plates in the server rack for maintenance while maintaining the cooling.

17. The method of claim 13, further comprising routing the heated liquid coolant to an external chilled water loop via the heat exchanger to dissipate heat from the data center.

18. (canceled)

19. The method of claim 13, further comprising dynamically allocating cooling resources between the cold plates based on real-time heat load measurements to optimize thermal performance.

20. The method of claim 13, further comprising adding or removing one or more manifolds, cold plates, or immersion tanks to accommodate changes in server capacity within the data center.

21. The data center cooling system of claim 1, further comprising an immersion tank configured to submerge at least a portion of the servers housed within the server rack in a dielectric liquid, wherein the dielectric liquid absorbs heat from the servers and operates concurrently with the liquid coolant in the cold plates; and
wherein the immersion tank is configured to incorporate circulation of the dielectric liquid to enhance heat dissipation and maintain a uniform temperature within the immersion tank.

22. The method of claim 13, further comprising immersing at least a portion of the servers housed within the server rack in a dielectric liquid contained within an immersion tank, wherein the dielectric liquid operates as a secondary cooling medium in conjunction with primary liquid coolant; and
wherein the dielectric liquid circulating within the immersion tank enhances heat dissipation and maintains a uniform temperature for submerged components.
